(19) United States
(12) Patent Application Publication
(10) Pub. No.: US 2016/0338211 A1
(43) Pub. Date: Nov. 17, 2016

(54) CIRCUIT BOARD AND METHOD OF MANUFACTURING THE SAME

(71) Applicant: SAMSUNG ELECTRO-MECHANICS CO., LTD., Suwon-si (KR)

(72) Inventors: Sang-Won HA, Suwon (KR); Tae-Gon LEE, Daejeon (KR); Kwang-Hee KWON, Busan (KR)

(73) Assignee: SAMSUNG ELECTRO-MECHANICS CO., LTD., Suwon-si (KR)

(21) Appl. No.: 15/082,467

(22) Filed: Mar. 28, 2016

(30) Foreign Application Priority Data
May 12, 2015 (KR) 10-2015-0066314

(51) Int. Cl. H05K 5/00; H05K 3/00; H05K 1/02; H05K 1/11; H05K 1/18

(52) U.S. Cl. CPC H05K 5/0017; H05K 1/115; H05K 1/111; H05K 1/181; H05K 1/0204; H05K 3/0017

(57) ABSTRACT

A circuit board includes a top surface; a bottom surface; and a heat-dissipating portion, wherein the heat-dissipating portion extends from the top surface of the circuit board to the bottom surface of the circuit board, and a first surface of the heat-dissipating portion is exposed out of the top surface of the circuit board, and a second surface of the heat-dissipating portion is exposed out of the bottom surface of the circuit board.

### CROSS-REFERENCE TO RELATED APPLICATIONS

This application claims the benefit under 35 USC 119(a) of Korean Patent Application No. 10-2015-0066314, filed on May 12, 2015 in the Korean Intellectual Property Office, the entire disclosure of which is incorporated herein by reference for all purposes.

### BACKGROUND

1. Field

The following description relates to a circuit board, a portable terminal including the same and a method of manufacturing the same.

2. Description of Related Art

To address today's electronic devices that are increasingly lighter, smaller and faster and have more functions and higher performances, various multilayered board technologies have been developed by forming a plurality of wiring layers on a circuit board, such as a printed circuit board (PCB). Some of these technologies have evolved to install electronic components, such as active devices or passive devices, in the multilayered board.

An increased amount of heat is generated as application processors (AP) connected to the multilayered board have more functions and higher performances.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a circuit board having improved heat-dissipating performance, a lighter weight, a thinner and smaller board, improved reliability, reduced noise and improved manufacturing efficiency. The circuit board includes a top surface; a bottom surface; and a heat-dissipating portion, wherein the heat-dissipating portion extends from the top surface of the circuit board to the bottom surface of the circuit board, and a first surface of the heat-dissipating portion is exposed out of the top surface of the circuit board, and a second surface of the heat-dissipating portion is exposed out of the bottom surface of the circuit board.

In another general aspect, the circuit board includes a heat-dissipating portion, which is made of a material having a high thermal conductivity and penetrates the circuit board between a top surface and bottom surface of the circuit board. The heat-dissipating portion may be made of a metallic material, such as, for example, copper, and in another embodiment, the heat-dissipating portion may be made of a non-metallic material having a high thermal conductivity, for example, graphite or graphene.

In another general aspect, a portable terminal comprising a display disposed on a front face, a case surrounding lateral faces and a back face. The portable terminal includes a circuit board, disposed between the case and the display, having a top surface; a bottom surface, and a heat-dissipating portion. The heat-dissipating portion extends from the top surface of the circuit board to the bottom surface of the circuit board. A first surface of the heat-dissipating portion is exposed out of the top surface of the circuit board, and a second surface of the heat-dissipating portion is exposed out of the bottom surface of the circuit board. The portable terminal further includes a heat-dissipating plate in contact with the bottom surface of the heat-dissipating portion; and a heat-dispersing part in contact with the heat-dissipating plate and disposed on one or more of the lateral faces or the back face, or any combination thereof, of the portable terminal.

In another general aspect, a method of manufacturing a circuit board having a heat-dissipating portion including a first heat-dissipating unit and a second heat-dissipating unit, the heat-dissipating portion extends from a bottom surface to a top surface of the circuit board, wherein a first surface of the heat-dissipating portion is exposed out of the top surface of the circuit board, and a second surface of the heat-dissipating portion is exposed out of the bottom surface of the circuit board. The method includes providing a first insulating layer; exposing an area of the first insulating layer to light; removing the light exposed area of the first insulating layer through etching to create a first cavity in the first insulating layer; filling the first cavity of the first insulating layer with a thermally conductive material to form the first heat-dissipating unit; disposing a second insulating layer on the first insulating layer and the first heat-dissipating unit; exposing an area of the second insulating layer to light; removing the light exposed area of the second insulating layer through etching to create a second cavity in the second insulating layer; and filling the second cavity of the second insulating layer with a thermally conductive material to form the second heat-dissipating unit. Other features and aspects will be apparent from the following detailed description, the drawings, and the claims.

### BRIEF DESCRIPTION OF DRAWINGS

FIG. 1 is a brief illustration of a circuit board in accordance with an embodiment;

FIG. 2 is a cross-sectional view along the I-I′ line of the circuit board shown in FIG. 1;

FIG. 3 is a magnified perspective view of the portion marked “A” in FIG. 2;

FIG. 4A is a brief illustration of a portable terminal in accordance with an embodiment;

FIG. 4B illustrates an arrangement of a circuit board in the portable terminal in accordance with an embodiment; and

FIG. 5A through FIG. 5H illustrate steps of a method of manufacturing a circuit board, in accordance with an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Terms such as “first” and “second” can be used in merely distinguishing one element from other identical or corresponding elements, but the above elements shall not be restricted to the above terms.

As used herein, the term “and/or” includes any and all combinations of one or more of the associated listed items.

Unless indicated otherwise, a statement that a first layer is “on” a second layer or a substrate is to be interpreted as covering both a case where the first layer directly contacts the second layer or the substrate, and a case where one or more other layers are disposed between the first layer and the second layer or the substrate.

Words describing relative spatial relationships, such as “below”, “beneath”, “under”, “lower”, “bottom”, “above”, “over”, “upper”, “top”, “left”, and “right”, may be used to conveniently describe spatial relationships of one device or elements with other devices or elements. Such words are to be interpreted as encompassing a device oriented as illustrated in the drawings, and in other orientations in use or operation. For example, an example in which a device includes a second layer disposed above a first layer based on the orientation of the device illustrated in the drawings also encompasses the device when the device is flipped upside down in use or operation.

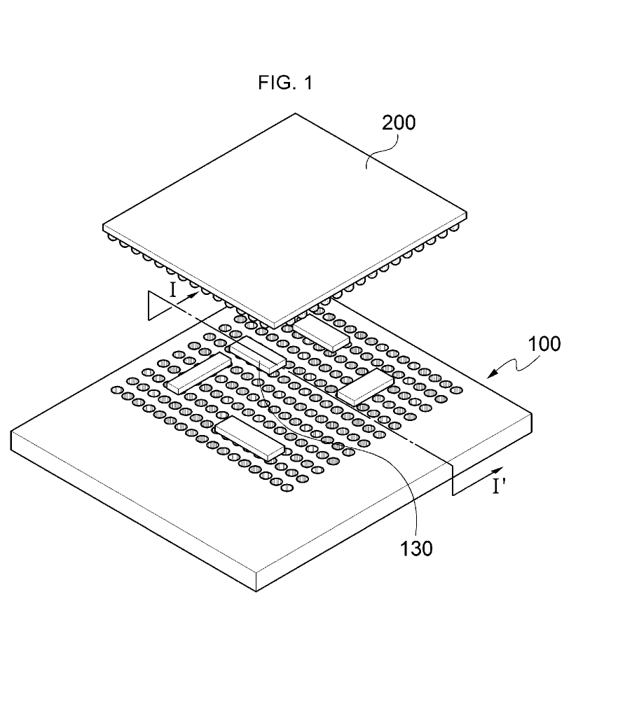

Referring to FIGS. 1 through 3, a circuit board 100 includes a heat-dissipating portion 110 extending through the circuit board 100, and an insulating portion 120. Specifically, a top surface of the heat-dissipating portion 110 is exposed out of a top surface of the circuit board 100, and a bottom surface of the heat-dissipating portion 110 is exposed out of a bottom surface of the circuit board 100. In this example, the heat-dissipating portion 110 is made of a material having a high thermal conductivity. Moreover, the heat-dissipating portion 110 is formed in a lump shape. In an embodiment, the heat-dissipating portion 110 may be formed in a cylindrical shape with a circular or polygonal base. Moreover, the heat-dissipating portion 110 may be made of a metallic material, for example, copper. In other embodiments, the heat-dissipating portion 110 may be made of a non-metallic material having a high thermal conductivity, for example, graphite or graphene.

The insulating portion 120 may have a single insulating layer or a plurality of insulating layers including, for example, a first insulating layer and a second insulating layer. In this example, the insulating portion 120 is made of a photosensitive insulating material, such as a photo imagable dielectric, and thus the heat-dissipating portion 110 is efficiently formed by performing photolithography.

The heat-dissipating portion 110 is configured to store heat or transfer the heat to a lower-temperature portion. The amount of heat the heat-dissipating portion 110 store or transfer varies according to a volume of the heat-dissipating portion 110. Therefore, with increase in the volume of the heat-dissipating portion 110, the amount of heat that can be stored or transferred by the heat-dissipating portion 110 is increased. Accordingly, as illustrated, the heat-dissipating portion 110 may be formed in the cylindrical shape. The cylindrical shape maximizes the volume of the heat-dissipating portion 110 for a given area of the bottom surface. Moreover, forming the top surface and the bottom surface in a polygonal shape, especially in a rectangular shape, would be well suited for the circuit board 100, which is increasingly smaller and has a finer pattern pitch, than forming the top surface and the bottom surface in a circular or elliptical shape. Moreover, as illustrated, the heat-dissipating portion 110 has a much greater volume than a general via, such as a first via V1. That is, a horizontal cross-section of the heat-dissipating portion 110 is bigger than a maximum value of a horizontal cross-section of, for example, the first via V1. Accordingly, the heat-dissipating portion 110 quickly absorbs the heat from a heat source and disperses the heat through other routes connected with the heat-dissipating portion 110.

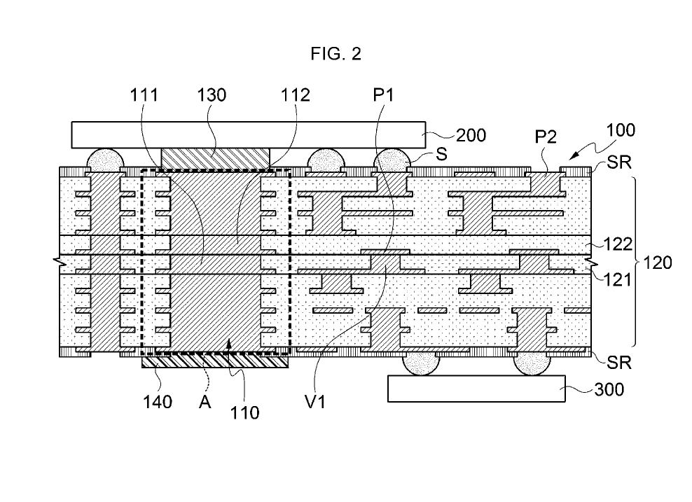

Referring to FIGS. 1 and 2, a first electronic component 200 is mounted on one side of the circuit board 100. In this example, the first electronic component 200 may be an integrated circuit, such as an application processor (AP), and generates heat during an operation. Moreover, in another embodiment, the first electronic component 200 may refer to a package board having an integrated circuit embedded therein or mounted on a surface thereof.

The heat generated due to the operation of the first electronic component 200 is measured to be relatively higher at a certain portion of the first electronic component 200. Such a portion is often referred to as a “hot spot.” The hot spot occur throughout the first electronic component 200 or near a particular portion of the first electronic component 200, for example, near a power source terminal of the first electronic component 200 or at an area of the first electronic component 200 where switching devices are relatively heavily concentrated.

In another example, the first electronic component 200 includes a region that has a relatively higher performance specification and a region that has a relatively lower performance specification. For instance, a first electronic component 200 having a processor connected with cores having a clock speed of 1.8 GHz in one region thereof and a processor connected with cores having a clock speed of 1.2 GHz in another region thereof.

The circuit board 100 in accordance with an embodiment has the heat-dissipating portion 110 disposed in an area adjacent to the hot spot. Accordingly, the heat generated from the hot spot is quickly transferred and dispersed to other regions of the circuit board 100. In an embodiment, the bottom surface of the heat-dissipating portion 110 is exposed on the bottom surface of the circuit board 100, and a heat-dissipating plate 140 is coupled to at least a portion of the exposed bottom surface of the heat-dissipating portion 110. Thus, the heat transferred through the heat-dissipating portion 110 is dispersed to the heat-dissipating plate 140.

At least a portion of the heat-dissipating portion 110 is disposed in an area vertically below the first electronic component 200. Furthermore, most of the heat-dissipating portion 110 is disposed in the area vertically below the first electronic component 200. Moreover, the top surface of the heat-dissipating portion 110 may have a smaller area than that of a top surface of the first electronic component 200. The area of the top surface of the heat-dissipating portion 110 corresponds to a width of the hot spot of the first electronic component 200. Accordingly, the heat from the hot spot is rapidly transferred to the heat-dissipating portion 110.

In one embodiment, the first electronic component 200 is coupled to the circuit board 100 through solder S. The solder S connects the first electronic component 200 to a second circuit pattern P2. Thus, the first electronic component 200 is affixed to the circuit board 100 and electrically connected with the circuit patterns. In this example, a portion of the second circuit pattern P2 is exposed to an outermost surface of the circuit board 100 and in order to serve as a connection pad. That is, the solder S is formed on the connection pad. Moreover, a solder resist layer SR, which is for exposing the connection pad and protecting the insulating portion 120 and remaining portions of the second circuit pattern P2, is disposed on the top surface and the bottom surface of the circuit board 100.

A first heat-transfer structure 130, which is formed in a similar shape and of a similar material as those of the heat-dissipating portion 110, rather than the general solder S, is interposed between the first electronic component 200 and the heat-dissipating portion 110. That is, for efficient transfer of the heat from the first electronic component 200 to the heat-dissipating portion 110, the first electronic component 200 and the heat-dissipating portion 110 are connected with each other using the first heat-transfer structure 130 formed in a lump shape with a material having a greater thermal conductivity than the general solder S. Accordingly, the heat generated from the first electronic component 200, especially from the hot spot, is quickly dispersed through a route formed by the first heat-transfer structure 130 and the heat-dissipating portion 110. Moreover, a plurality of solder balls are disposed on a bottom surface of the second electronic component 200 to fix the second electronic component 200 to the circuit board 100 and provide an electrical connection therebetween. By having the first heat-transfer structure 130 contact the first electronic component 200 between the solder balls allows for rapid dispersion of the heat from the first electronic component 200 and allows to the first electronic component 200 to have a small size. In addition, by disposing the first heat-transfer structure 130 between the solder balls, a height required when the first electronic component 200 and the circuit board 100 are coupled by the solder balls is not increased by the first heat-transfer structure 130, thereby contributing to a slim electronic component.

The heat-dissipating portion 110 or the connection pad may have any of a variety of surface-treated layers, for example, nickel-gold plated layer, formed on a surface thereof. Moreover, a material having a high thermal conductivity and a strong adhesive capability may be interposed between the heat-dissipating portion 110 and the first heat-transfer structure 130 or between the first heat-transfer structure 130 and the first electronic component 200.

In an embodiment, the first heat-transfer structure 130 is integrally formed with the heat-dissipating portion 110, and in another embodiment, the first heat-transfer structure 130 is integrally formed with the first electronic component 200. Moreover, it is possible that a dummy terminal is disposed at a portion of the first electronic component 200 that is in contact with the first heat-transfer structure 130, whereas the dummy terminal is not utilized as a path for electric power or electric signals but for simply transferring the heat.

Another electronic component, namely, a second electronic component 300, may be disposed on the bottom surface of the circuit board 100.

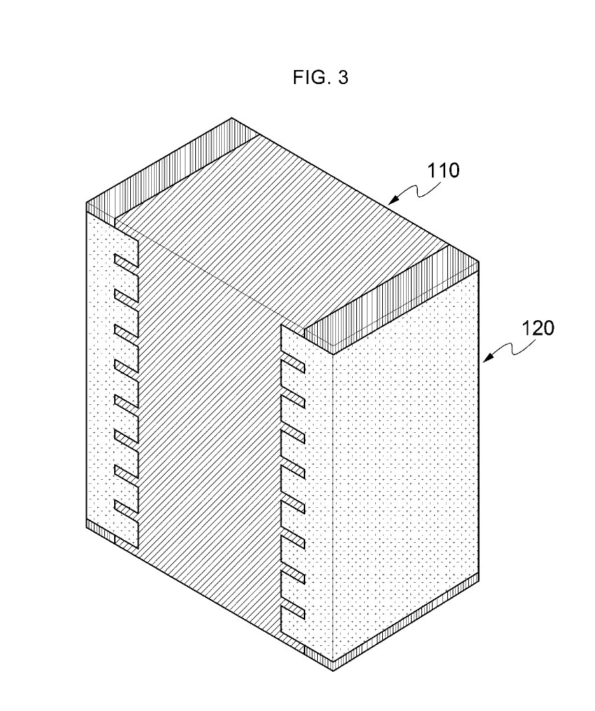

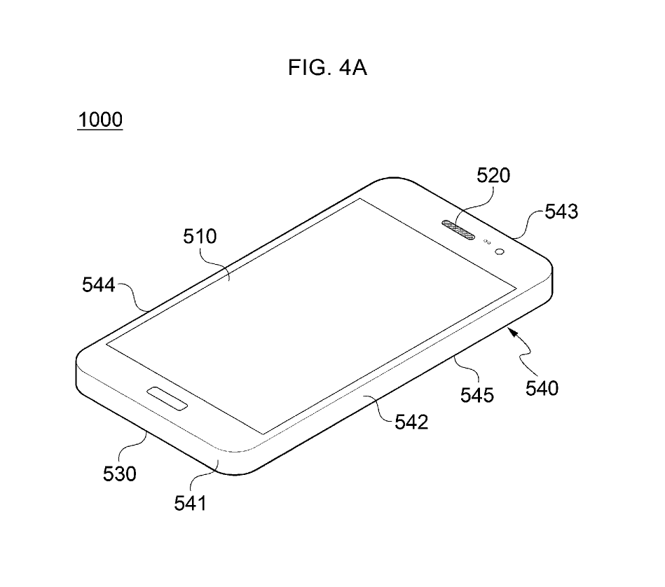

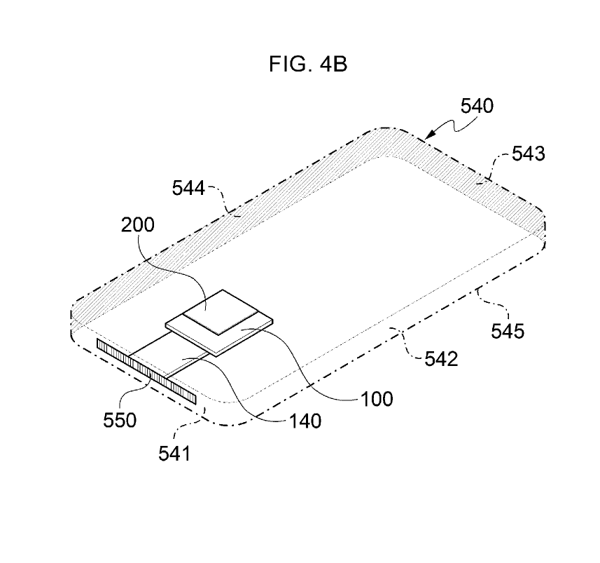

Referring to FIG. 4A and FIG. 4B, the portable terminal 1000, such as for example a smartphone or a tablet computer, generally has a display 510 disposed at a front face thereof and includes a case 540 surrounding a back face and lateral faces thereof. Moreover, the display 510 outputs a graphic user interface (GUI) for a predetermined content or operation, and is equipped with a touch panel to receive a user input. In addition, the portable terminal 1000 is equipped with a speaker 520, for outputting a sound, and a microphone 530, for inputting a sound from an outside.

The above described circuit board 100 is generally disposed between the display 510 and the case 540. The heat generated by the first electronic component 200 travels through the heat-dissipating portion 110 and is dispersed through the heat-dissipating plate 140, which is in contact with the heat-dissipating portion 110. In the case where the portable terminal 1000 is a smartphone, a user would grab a left lateral face and a right lateral face of the portable terminal 1000 and place the display 510 close to a cheek of the user to be engaged in a telephone communication. Considering such a common example of use, if the heat generate by the portable terminal 1000 were transferred to the display 510, the user would experience a discomfort and might even have a skin damage such as a low-temperature burn.

Accordingly, to solve the above-described problem, the portable terminal 1000 in accordance with an embodiment includes a heat-dispersing part 550, which is contact with one side of the heat-dissipating portion 110, on a lateral face 541, 542, 543, 544 or a back face 545 of the portable terminal 1000. Furthermore, in an example, the heat-dispersing part 550 is disposed on a lower lateral face 541 or an upper lateral face 543 of the portable terminal 1000. Accordingly, in the case where the user grips the portable terminal 1000, it is possible to lower the risk of low-temperature burn that may occur when a hand of the user makes contact with a left lateral face 542, a right lateral face 544 and the back face 545.

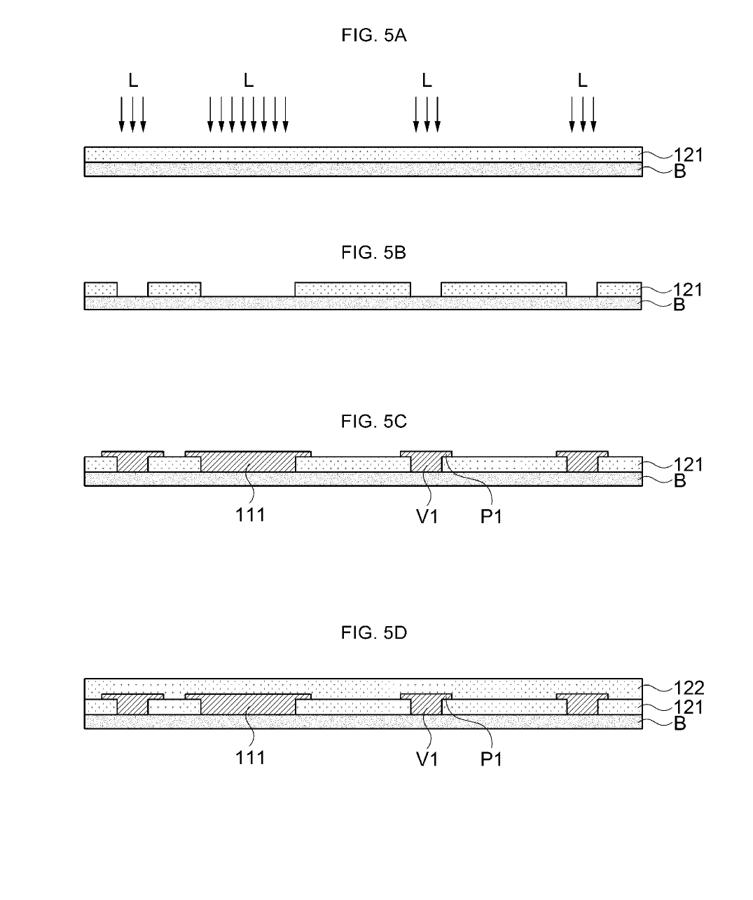

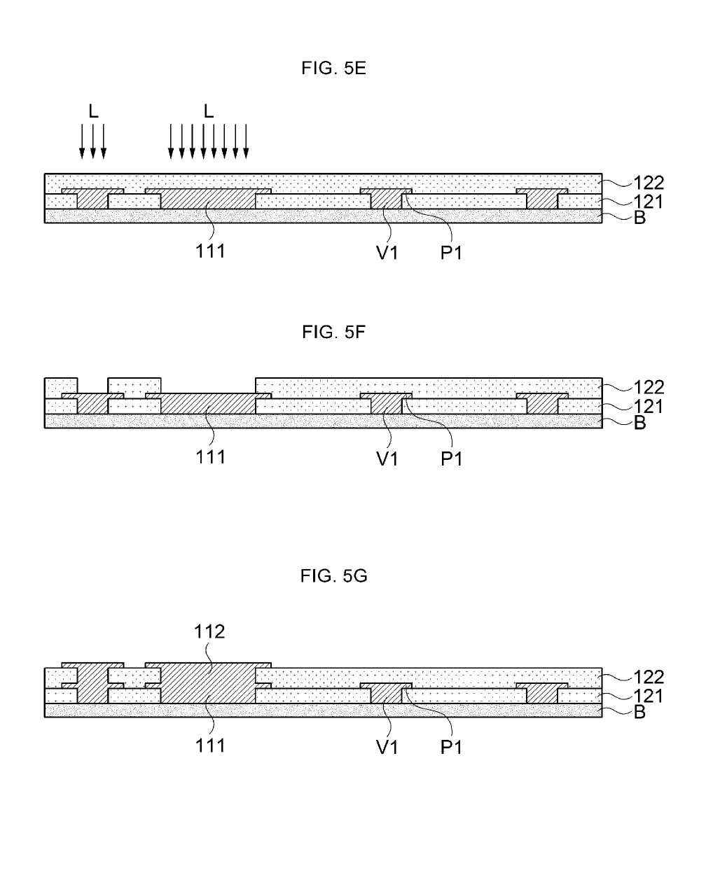

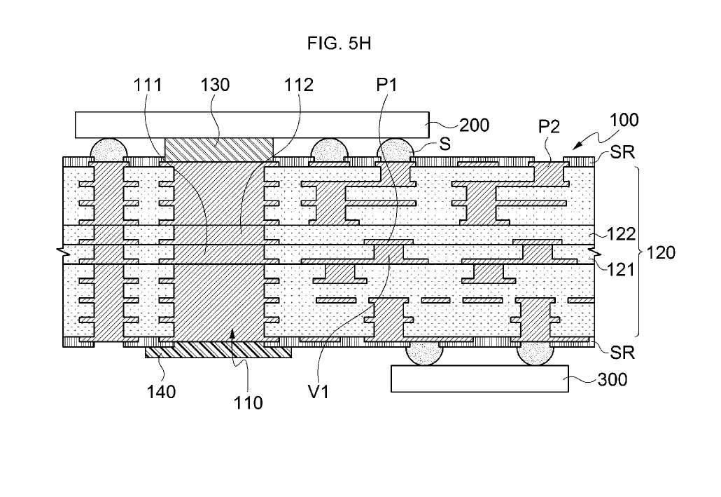

Referring to FIG. 5A through FIG. 5H, in a method of manufacturing a circuit board in accordance with an embodiment, a circuit board 100 encompassing a heat-dissipating portion 110 is manufactured through photolithography.

First, light L is radiated at locations of a first insulating layer 121 where a first heat-dissipating unit 111 is to be formed. In this example, the first heat-dissipating unit 111 refers to a portion of the heat-dissipating portion 110. Moreover, the photolithography is performed by selectively radiating the light L at predetermined locations by use of a mask in which a pattern is formed. Moreover, the light L may be selectively radiated by use of a laser, without the use of the mask. While radiating the light L at the locations where the first heat-dissipating unit 111 is to be formed, the light L may be also radiated onto a location where a first via V1 for signal transfer is to be formed. Then, portions of the first insulating layer 121 that were irradiated by the light L are removed using chemical etching.

Alternatively, it is possible to remove the first insulating layer 121 by allowing the portions irradiated the light L to be cured and remove portions of the insulating layer 121 not irradiated by the light L.

Next, the first heat-dissipating unit 111 is formed by filling the removed portions of the first insulating layer 121 with a thermally conductive material. In this example, the first heat-dissipating unit 111 may be made of, for example, copper, which has a high thermal conductivity, and disposed on in the removed portions through plating or paste-coating. A first circuit pattern P1 may be simultaneously formed, as necessary.

In the above steps, the first insulating layer 121 may be supported by a base board B.

A second insulating layer 122 is disposed on the first insulating layer 121. Portions of the second insulating layer 122 is irradiated by light L. The irradiated portions of the second insulating layer 122 are removed before a second heat-dissipating unit 112 is formed. The above-described steps of removing irradiated portions of a layer and filling cavities formed by removing the irradiated portions with a thermally conductive material are repeated to complete the manufacture of the circuit board 100. The number of steps to be performed on the circuit board 100 vary according to a desired number of layers for the circuit board 100.

As described above, by forming the heat-dissipating portion 110 by exposing an insulating layer made of a photosensitive insulating material, the heat-dissipating portion 110 is securely affixed to the insulating portion 120, and the heat-dissipating portion 110 has an efficient structure having a cross-sectional shape and volume with which the heat-dissipating performance is maximized.

As a non-exhaustive example only, a device or terminal as described herein may be a mobile device, such as a cellular phone, a smart phone, a wearable smart device (such as a ring, a watch, a pair of glasses, a bracelet, an ankle bracelet, a belt, a necklace, an earring, a headband, a helmet, or a device embedded in clothing), a portable personal computer (PC) (such as a laptop, a notebook, a subnotebook, a netbook, or an ultra-mobile PC (UMPC), a tablet PC (tablet), a phablet, a personal digital assistant (PDA), a digital camera, a portable game console, an MP3 player, a portable/personal multimedia player (PMP), a handheld e-book, a global positioning system (GPS) navigation device, or a sensor, or a stationary device, such as a desktop PC, a high-definition television (HDTV), a DVD player, a Blu-ray player, a set-top box, or a home appliance, or any other mobile or stationary device capable of wireless or network communication. In one example, a wearable device is a device that is designed to be mountable directly on the body of the user, such as a pair of glasses or a bracelet. In another example, a wearable device is any device that is mounted on the body of the user using an attaching device, such as a smart phone or a tablet attached to the arm of a user using an armband, or hung around the neck of the user using a lanyard.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A circuit board comprising:
a top surface;
a bottom surface; and
a heat-dissipating portion,
wherein the heat-dissipating portion extends from the top surface of the circuit board to the bottom surface of the circuit board, and
a first surface of the heat-dissipating portion is exposed out of the top surface of the circuit board, and a second surface of the heat-dissipating portion is exposed out of the bottom surface of the circuit board.

2. The circuit board as set forth in claim 1, further comprising an insulating portion made of a photosensitive insulating material,
wherein the heat-dissipating portion is in contact with the insulating portion.

3. The circuit board as set forth in claim 1, further comprising a circuit pattern and a via,
wherein a horizontal cross-sectional area of the heat-dissipating portion is greater than a maximum horizontal cross-sectional area of the via.

4. The circuit board as set forth in claim 3, wherein a cross-section of the heat-dissipating portion is in a rectangular shape.

5. The circuit board as set forth in claim 1, wherein a plurality of solder balls are disposed on a lower surface of an electronic component and in contact with the upper surface of the circuit board.

6. The circuit board as set forth in claim 5, further comprising:
a plurality of connection pads in contact with the plurality of solder balls, respectively; and
a heat-transfer structure comprising a thermally conductive material,
wherein the heat-transfer structure is disposed between and separate from the connection pads, and
a bottom surface of the heat-transfer structure is in contact with the first surface of the heat-dissipating portion and a top surface of the heat-transfer structure is in contact with the lower surface of the electronic component.

7. The circuit board as set forth in claim 1, further comprising a heat-dissipating plate in contact with the second surface of the heat-dissipating portion.

8. A portable terminal comprising a display disposed on a front face, a case surrounding lateral faces and a back face, the portable terminal comprising:
a circuit board, disposed between the case and the display, comprising:
a top surface;
a bottom surface;
a heat-dissipating portion, wherein the heat-dissipating portion extends from the top surface of the circuit board to the bottom surface of the circuit board, a first surface of the heat dissipating portion is exposed out of the top surface of the circuit board, and a second surface of the heat dissipating portion is exposed out of the bottom surface of the circuit board;
a heat-dissipating plate in contact with the bottom surface of the heat-dissipating portion; and
a heat-dispersing part in contact with the heat-dissipating plate and disposed on one or more of the lateral faces or the back face, or any combination thereof of the portable terminal.

9. A method of manufacturing a circuit board comprising a heat-dissipating portion comprising a first heat-dissipating unit and a second heat-dissipating unit, the heat-dissipating portion extends from a bottom surface to a top surface of the circuit board, wherein a first surface of the heat-dissipating portion is exposed out of the top surface of the circuit board, and a second surface of the heat-dissipating portion is exposed out of the bottom surface of the circuit board, the method comprising:
providing a first insulating layer;
exposing an area of the first insulating layer to light;
removing the light exposed area of the first insulating layer through etching to create a first cavity in the first insulating layer;
filling the first cavity of the first insulating layer with a thermally conductive material to form the first heat-dissipating unit;
disposing a second insulating layer on the first insulating layer and the first heat-dissipating unit;
exposing an area of the second insulating layer to light;
removing the light exposed area of the second insulating layer through etching to create a second cavity in the second insulating layer; and
filling the second cavity of the second insulating layer with a thermally conductive material to form the second heat-dissipating unit.

10. The method as set forth in claim 9, wherein the first insulating layer and the second insulating layer are made of a photosensitive insulating material.

11. The method as set forth in claim 9, wherein at least one of the first heat-dissipating unit and the second heat-dissipating unit is formed through plating or paste-coating.
